(19) United States
(12) Patent Application Publication
(10) Pub. No.: US 2009/0084921 A1
(43) Pub. Date: Apr. 2, 2009

(54) Universal holder

(75) Inventor: Su-Ting Tu, Hsinchu (TW)

Correspondence Address: BACON & THOMAS, PLLC, 625 SLATERS LANE, FOURTH FLOOR, ALEXANDRIA, VA, 22314-1176, US

(73) Assignee: Coretronic Corporation, Hsinchu (TW)

(21) Appl. No.: 12/213,065

(22) Filed: Jun. 13, 2008

(30) Foreign Application Priority Data
Oct. 2, 2007 (TW) 096216422

(51) Int. Cl. A47B 96/06; F16M 11/00; H05K 7/14

(52) U.S. Cl. 248/313; 248/689; 248/229.1

(57) ABSTRACT

An universal holder is applied to a display for loading an auxiliary apparatus. The universal holder has a bottom plate, a first clamp and a second clamp. The bottom plate is combined with the display. The bottom plate has a first rail and a second rail. The first rail is not parallel to the second rail. The first clamp is disposed on the first rail. The second clamp is disposed on the second rail, and cooperates with the first clamp to fasten the auxiliary apparatus.

### BACKGROUND OF THE INVENTION

(1) Field of the Invention

The present invention relates to an universal holder, and more particularly relates to an universal holder applied in a display.

(2) Description of the Prior Art

A digital display is used as a media in multimedia digital signage, electronic billboards or LCD signboard, which communicate with audiences by playing high quality films, cartoons, images and characters.

Referring to FIG. 1, a digital display 100 is disposed in big constructions like government offices, restaurants, hospitals, transportation centers, university or public walls and pillars to display telecast signal or public messages. The digital display 100 is usually connected to some auxiliary apparatuses 102, such as a remote display unit or an external TV tuner box, so as to receive or control telecast signals or public messages. The auxiliary apparatuses 102 are connected to a host computer 103 to conveniently set and manage the digital display 100.

However, it is always inconvenient to place the host computer 103 or the auxiliary apparatuses 102 beside the display 100 in public. Therefore, some problems the auxiliary apparatuses 102 may face are that it needs to open up another placing space or there is even no placing space.

### SUMMARY OF THE INVENTION

Accordingly, the objective of the present invention is to provide an universal holder applied to a display for loading all sizes or shapes of auxiliary apparatuses to save space.

For one or part of or all objectives mentioned or other objectives, one embodiment of the present invention is an universal holder. The universal holder has a bottom plate, a first clamp and a second clamp. The bottom plate is combined with a display. The bottom plate has a first rail and a second rail. The first rail is not parallel to the second rail. The first clamp is disposed on the first rail. The second clamp is disposed on the second rail, and cooperates with the first clamp to fasten an auxiliary apparatus.

Another embodiment of the present invention is a display set, including a display, an universal holder combined with the display and an auxiliary apparatus. The auxiliary apparatus is fixed on the bottom plate by a plurality of clamps and is electrically connected to the display.

The mentioned universal holder or display set further includes a third clamp. The bottom plate has a third rail. The third clamp is disposed on the third rail. The third rail is disposed on the extension cord of the first rail. The mentioned universal holder or display set further includes a linkage unit. The first clamp and the third clamp are connected to the linkage unit respectively. When the first clamp is moved, the third clamp is coupled to move in the opposite direction by leakage unit to fasten the auxiliary apparatus. Each clamp has a L-shaped bend and a bolt which locates the clamp in its corresponding rail.

The bottom plate has two sheet components, connected in a T-shaped. The first rail and the second rail are disposed on two sheet components respectively. There is at least one long strip hole in the bottom plate. The long strip hole is used for a screw to thread through to fix the bottom plate on the display

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The present invention will now be specified with reference to its preferred embodiment illustrated in the drawings, in which

FIG. 1 is a schematic view of a conventional display board setting;

FIG. 2 is chart showing a first preferable embodiment of an universal holder according to the present invention;

FIG. 3 is chart showing a first preferable embodiment of the universal holder disposed on the back of a display according to the present invention;

FIG. 4 is chart showing a first preferable embodiment of a display set according to the present invention;

FIG. 5 is chart showing another preferable embodiment of the universal hold according to the present invention;

FIG. 6 is a chart showing a second preferable embodiment of the universal holder according to the present invention; and

FIG. 7 is a chart showing a third preferable embodiment of universal holder according to the invention.

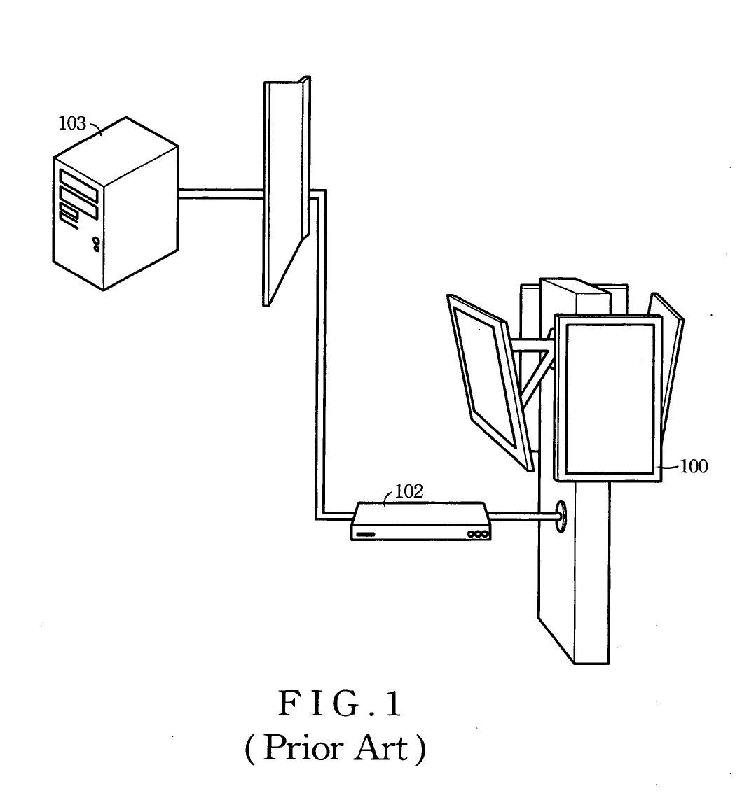

### DESCRIPTION OF THE PREFERRED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

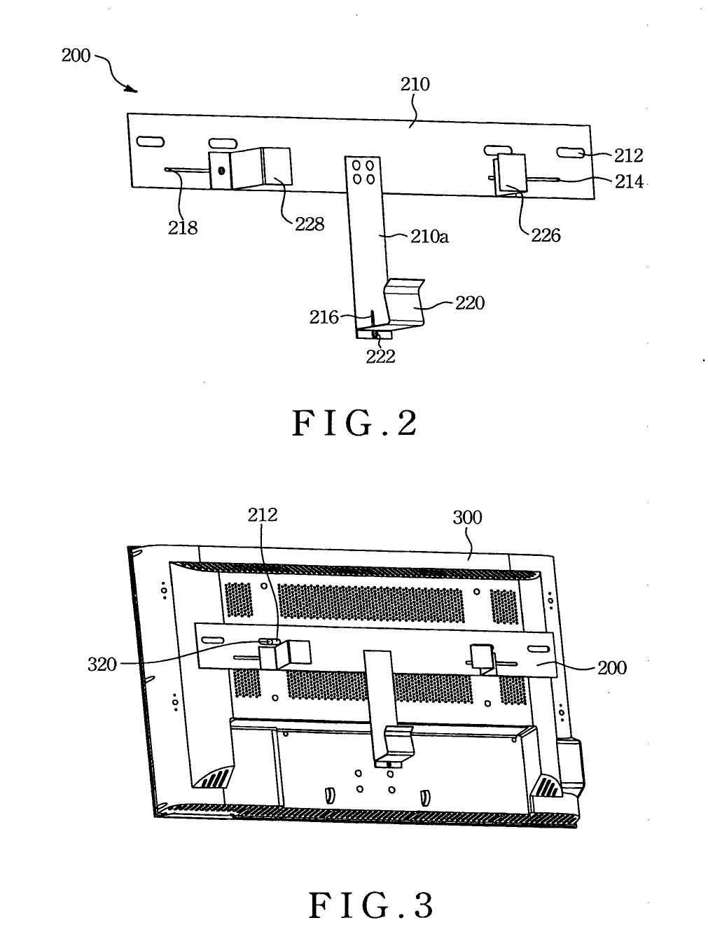

Refer to FIG. 2 for the schematic view of an universal holder 200. The universal holder 200 includes two sheet components 210 and 210a, and three clamps 220, 226 and 228. Two sheet components 210 and 210a are connected in T-shaped, one is horizontal and the other is lengthways. Left and right ends of the sheet component 210 have respectively two horizontal long strip holes 212 which are used for screws (not shown) to thread through to fix the sheet component 210 to the back side of the display. The sheet component 210 has two horizontal rails 218 and 214. The clamps 228 and 226 are disposed on the rails 218 and 214 respectively and may move left and right along the rails 218 and 214 respectively. The sheet component 210a has a lengthways rail 216. The clamp 220 is disposed on the rail 216 and may move up and down along the rail 216.

Refer to FIG. 2, the rails 214, 216 and 218 all have smooth rail margins for sliding the clamps 226, 220, 228. Preferably, the rail 214 is disposed on the extension cord of the rail 218. The directions of the rail 216 is vertical to the rails 214 and 218, so that the clamps 228, 226, 220 may fasten an object, such as an auxiliary apparatus which is a remote display or an external TV tuner box which is electrically connected with the display. Each of the clamps 220, 226 and 228 has a bolt 222. After a user moves the clamps 220, 226 or 228 along the rails 216, 214 or 218 to the destination and then spins the bolt 222, the corresponding clamps 220, 226 or 228 are fixed position on the rail 216, 214 or 218.

Refer to FIG. 3 , a screw 320 is threaded through a long strip hole 212 in the universal holder 200 to lock the universal holder 200 to the back side of a display 300. The display 300 for example, is a digital billboard, a plasma TV or a liquid crystal TV.

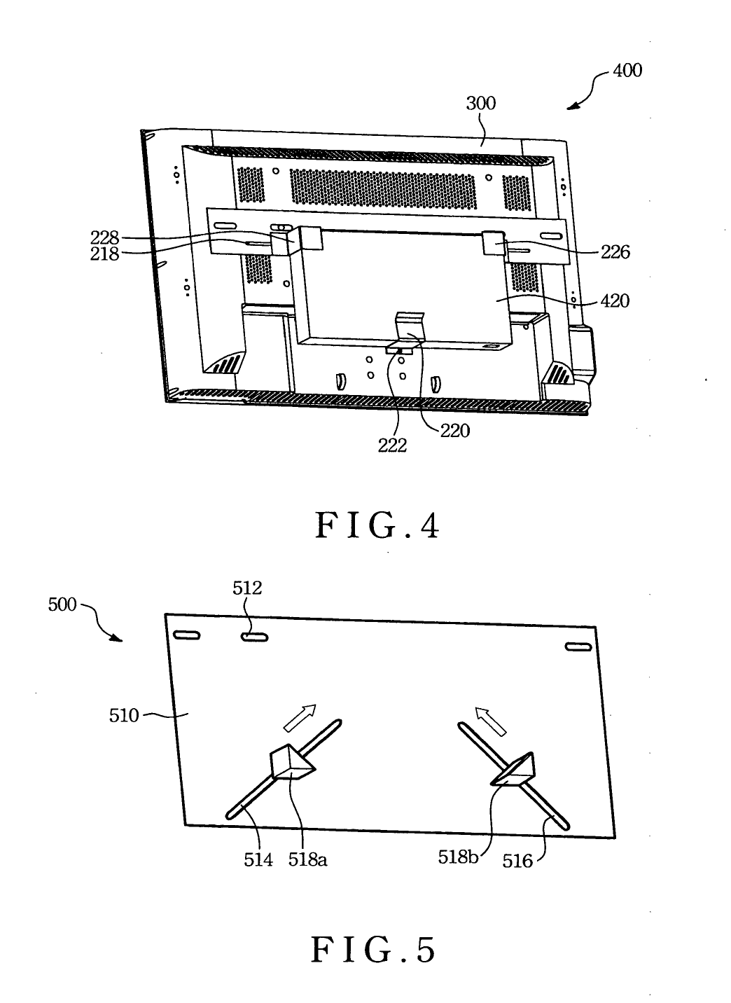

Refer to FIG. 4, an auxiliary apparatus 420 is fastened by the clamps 220, 226 and 228 of the universal holder 200. In this way, the display 300, the universal holder 200 and the auxiliary apparatus 420 form a display set 400. The auxiliary apparatus 420 is fixed on the universal holder 200. The universal holder 200 is combined to the back side of the display 300. Therefore, the back space of the display 300 may be used for placing the auxiliary apparatus 420. The auxiliary apparatus 420 is electrically connected to the display 300 to transmit audio or video signals to the display 300.

Preferably, the universal holder 200 has a plurality of adjustable clamps 220, 226 and 228 to suit all shapes and sizes of the auxiliary apparatuses 420. Firstly, the user locks the universal holder 200 to the back side of the display 300 and places the auxiliary apparatus 420 into the universal holder 200, and then moves the clamps 220, 226 and 228 to the position for clamping the auxiliary apparatus 420. Finally, the user spins the bolt 222 to avoid the clamps 220, 226 and 228 sliding at random and the auxiliary apparatus 420 falling off.

Refer to FIG. 5 for the schematic view of a simplified universal holder 500. The universal holder 500 has a bottom plate 510 which functions as the mentioned sheet component 210 of FIG. 2, and at least two clamps 518a and 518b. The bottom plate 510 has a plurality of holes 512 and rails 514, 516. The holes 512 are used to dispose the bottom plate 510 to the display 300. Especially, the rail 514 is not parallel to the rail 516, but across or vertical. The clamp 518a is disposed on the rail 514. The clamp 518b is disposed on rail 516 to cooperate with the clamp 518a to fasten the auxiliary apparatus.

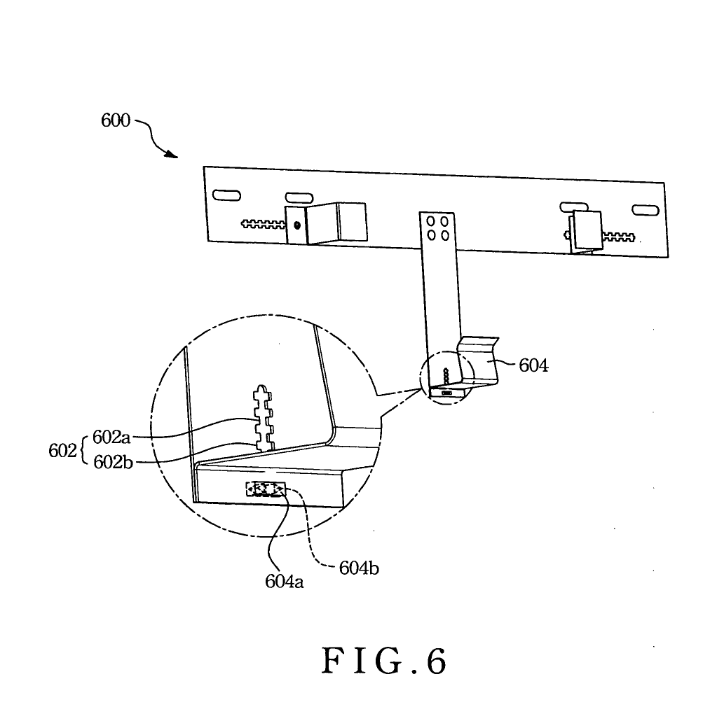

Refer to FIG. 6, an universal holder 600 has a dentate rail margin. When moving along a rail 602, the clamp 604 is located by an orientation unit. In this embodiment, a move key 604a is used as the orientation unit of the clamp 604. Thereinafter, an orientation method of the move key 604a is illustrated. The move key 604a has a flexible part 604b. When the move key 604a is moved to a narrow part 602a as one part of rail 602, the flexible part 604b is compressed inside from its two sides by upwards pushing force. When ascending to a wide part 602b, the flexible part 604b recovers and gets stuck in the wide part 602b. In general, the structure of the orientation unit needs to suit the rails. The abovementioned bolt 222 and the move key 604a are different orientation units.

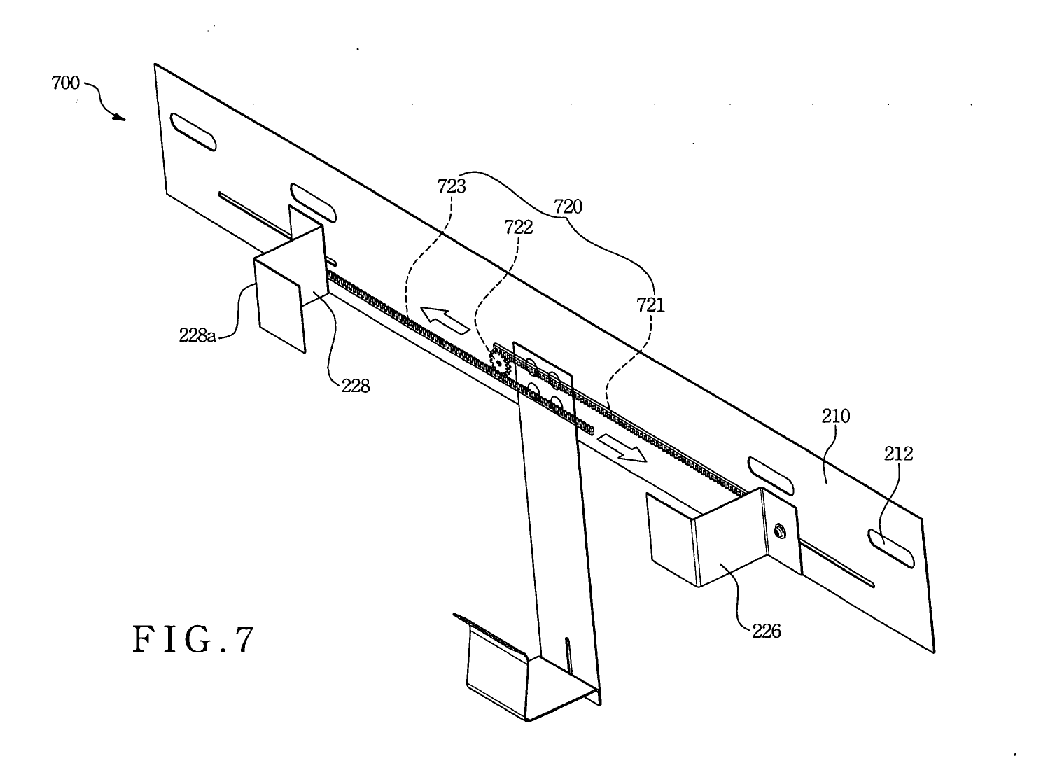

Refer to FIG. 7, an universal holder 700 has a linkage unit 720. The clamps 226 and 228 are connected to the linkage unit 720 respectively. The structure is illustrated as follows. The linkage unit 720 has a gear 722 and two slide rails 723 and 721. One end of the slide rail 723 is fixed to the clamp 228 and the other end of the slide rail 723 slides with the rotating of the gear 722. One end of the slide rail 721 is fixed to the clamp 226 and the other end slides with the turn of the gear 722. The direction of the slide rail 721 is opposite to that of the slide rail 723. Therefore, when the clamp 228 is moved, the clamp 226 is coupled to move reversely to fasten or loosen the auxiliary apparatus 420.

For all embodiments mentioned above, the long strip hole 212 is used to lock the universal holder 200 to the display 300 according to the different locations of screw hole in the display 300. The long strip hole 212 may alter the location or shape depending on the practical requirements. When enclosed in the universal holder 200, the auxiliary apparatus 420 is fixed and fastened from left, right and bottom by the universal holder 200. The left and right clamps 226 and 228 are used to restrain the left and right movement of the auxiliary apparatus 420. Middle clamp 220 is used to fix and fasten the bottom of the auxiliary apparatus 420. Therefore, the auxiliary apparatus 420 is fastened in the universal holder 200.

There are at least two rails unparallel or vertical, or three rails unparallel among the rails 214, 216 and 216. The clamp is not limited to any shape. Refer to FIG. 7, the clamp 228 uses a L-shaped bend 228a to increase effect of fastening.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. An universal holder applied to a display for loading an auxiliary apparatus, the universal holder comprising:
a bottom plate combined with the display, and having a first rail and a second rail, wherein the first rail is not parallel to the second rail;
a first clamp disposed on the first rail; and
a second clamp disposed on the second rail, and cooperated with the first clamp to fasten the auxiliary apparatus.

2. The universal holder of claim 1, further comprising a third clamp, wherein the bottom plate has a third rail, and wherein the third clamp is disposed on the third rail.

3. The universal holder of claim 2 wherein the third rail is disposed on the extension cord of the first rail.

4. The universal holder of claim 3, further comprising a linkage unit, wherein the first clamp and third clamp are connected to the linkage unit respectively.

5. The universal holder of claim 1, wherein the first rail is vertical to the second rail.

6. The universal holder of claim 1, wherein the bottom plate comprises two sheet components connected in T-shaped, and the first rail and the second rail are disposed on the two sheet components respectively.

7. The universal holder of claim 1, wherein the first clamp and the second clamp have a L-shaped bend respectively.

8. The universal holder of claim 1, wherein the bottom plate has a long strip hole for a screw to thread through, so as to fix the bottom plate to the display.

9. The universal holder of claim 1,wherein the second clamp has a bolt to fix the second clamp to the second rail.

10. A display set comprising:
a display;
an universal holder comprising:
a bottom plate combined with the display, and having a first rail and a second rail, wherein the first rail is not parallel to the second rail;
a first clamp disposed on the first rail; and
a second clamp disposed on the second rail; and
an auxiliary apparatus electrically connected to the display, fastened by the first and second clamps and fixed to the bottom plate.

11. The display set of claim 10, wherein the universal holder further comprises s a third clamp, and the bottom plate has a third rail for the third clamp disposed thereon.

12. The display set of claim 11, wherein the third rail is disposed on the extension cord of the first rail.

13. The display set of claim 12, wherein the universal holder further has a linkage unit connected with the first and third clamps respectively.

14. The display set of claim 10, wherein the first rail is vertical to the second rail.

15. The display set of claim 10, wherein the bottom plate comprises two sheet components connected in T-shaped, and the first rail and the second rail are disposed on the two sheet components respectively.

16. The display set of claim 10, wherein the first clamp and the second clamp have a L-shaped bend respectively.

17. The display set of claim 10, wherein the bottom plate has a long strip hole for a screw to thread through, so as to fix the bottom plate to the display.

18. The universal holder of claim 1, wherein the second clamp has a bolt to fix the second clamp to the second rail.
